(19) United States
(12) Patent Application Publication
(10) Pub. No.: US 2007/0205817 A1
(43) Pub. Date: Sep. 6, 2007

(54) Method, circuit and system for detecting a locked state of a clock synchronization circuit

(76) Inventors: Tyler Gomm, Boise, ID (US); Kang Yong Kim, Boise, ID (US); Scott Smith, Plano, TX (US); Jongtae Kwak, Boise, ID (US)

Correspondence Address: TRASK BRITT, P.C./ MICRON TECHNOLOGY, P.O. BOX 2550, SALT LAKE CITY, UT, 84110, US

(21) Appl. No.: 11/367,914

(22) Filed: Mar. 3, 2006

(51) Int. Cl. H03L 7/06

(52) U.S. Cl. 327/158

(57) ABSTRACT

Locked state detection circuits, devices, systems, and methods for detecting a locked or synchronized state of a clock synchronization circuit are described. Detection of a locked state includes a circuit including a phase detector configured to generate a delay adjustment signal in response to comparison of a forward path signal indicative of an external clock signal and a feedback path signal indicative of an output clock signal. The circuit further includes a trend detector operably coupled to the delay adjustment signal and configured to generate a locked signal indicative of an in-phase steady-state between the external clock signal and the output clock signal.

### BACKGROUND OF THE INVENTION

1. Field of the Invention

The present invention relates generally to memory devices and, more particularly, to memory devices adapted to receive input data and provide output data synchronized with a common external clock signal.

2. State of the Art

Integrated circuits, including memory and processors, which operate in synchronization with an external clock signal, typically generate an internal clock signal for gating the rippling nature of logic and for staging synchronous steps. Because of the inherent latencies associated with successive levels of propagation, the internal clock signal may be delayed when compared with the external clock signal. Such a delay may cause deterioration in the performance of the device during high-frequency operation. For example, during operation at high frequencies, the access time (i.e., the time required for outputting data after receipt of an external clock signal) may become longer than the time required for generating an internal clock signal from the received external clock signal.

Approaches have been explored for reducing the deterioration of the performance of a memory device at higher frequencies; one approach includes synchronizing the internal clock signal with the external clock signal. One synchronization implementation includes a delay locked loop (DLL) circuit which is used as an internal clock signal generator. DLL circuits typically use an adjustable delay line comprised of a series of connectable delay elements. Digital information such as shifting commands is used to either include or exclude a certain number of delay elements within a delay line. In a conventional DLL circuit, a clock input buffer accepts an external clock as an input signal and transmits the signal to one or more delay elements of the delay line. The delay of the delay path is increased from a minimum setting until the edge of the delayed reference clock is eventually time-shifted just past the next corresponding edge of the reference clock. As an element of a conventional DLL circuit, a digital phase detector controls the delay line propagation delay so that the delayed clock remains synchronized with the external or reference clock.

Conventional DLL circuits suffer from numerous drawbacks in terms of loop stability and lock time, which are very significant performance parameters for DLL circuits. In order to acquire a quick lock, the phase detector has to update as soon as possible. On the other hand, noise and long loop intrinsic delay require filtering to slow down the update rate due to desirable loop stability. Traditionally, the DLL circuits preferably operate within a wide frequency range, and the loop time delay is dictated by the highest frequency. In short, the loop time delay is translated to be the number of clock cycles the phase detector waits until the next comparison. Under process, voltage, and temperature variations, the response time may be two cycles for low-speed operation and ten or more cycles for high-speed operation.

Since devices, such as memory devices, that incorporate a clock synchronization circuit like a DLL circuit dictate internal timing and readiness of the device, there is a need for other circuits within the device to respond to a locked or phase-equal state of the DLL circuit. For example, knowledge of an achieved locked or phase-equal state of the DLL circuit may be used by external circuitry, such as On Die Termination (ODT) circuits, to indicate that circuits may transition from an asynchronous timing (e.g., using external clocking as a reference) to synchronous timing (e.g., using the DLL circuit derived output clock). Additionally, DLL circuits may enter power-conservation modes of operation but must have knowledge of a locked state before, for example, a power-saving reduced-sampling scheme may be utilized.

Conventional methods for detecting a locked or phase-equal state of the DLL circuit have relied on the accuracy of the phase detector to indicate that the system is locked or in a quiescent state. Reliance on the inherent hysteresis of the phase detector creates a “deadband” that is indicative of a quiescent state. For higher frequency operation, the hysteresis of the phase detector needs to be set to a value greater than the input clock jitter; otherwise a quiescent state would never be attainable, and any external circuitry that relies on the attainment of a locked state may never or at least sporadically be enabled. Furthermore, as specifications for the tolerance for input external clock jitter have increased, and as the phase detection resolution requirements increase, resolving a quiescent state based on the phase detector hysteresis becomes problematic.

Therefore, a need exists for a method and circuit for obtaining a locked signal indicative of an acceptable phase-equal condition between the external clock signal and a generated output clock signal regardless of the resolution of the phase detector accuracy and the input clock jitter. A need, therefore, exists to improve the performance of DLL circuits and overcome, or at least reduce, one or more of the problems set forth above.

### BRIEF SUMMARY OF THE INVENTION

The present invention includes methods, circuits, and systems for detecting a locked or in-phase state of a clock synchronization circuit, an example of which is a delay locked loop circuit. In one embodiment of the present invention, a clock synchronization circuit includes a delay line, an I/O model, and a phase detector. The delay line includes first and second inputs and an output with the first input configured to receive an external clock signal via an input driver. The output of the delay line is configured to couple with an output driver to generate an output clock signal. The I/O model includes an output and an input with the input of the I/O model configured to couple with the output of the delay line. The I/O model is further configured to model the intrinsic delay of an output driver and an input driver. The phase detector generates a delay adjustment signal and includes forward and feedback path inputs and an output operably coupled to the second input of the delay line. The forward path input couples to the first input of the delay line with the feedback path input coupling to the output of the I/O model. The clock synchronization circuit further includes a trend detector configured to generate a signal indicative of a locked state of the clock synchronization circuit.

In another embodiment of the present invention, a delay locked loop circuit includes a phase detector configured to generate a delay adjustment signal in response to comparison of a forward path signal indicative of an external clock signal and a feedback signal indicative of an output clock signal. The delay locked loop circuit further includes a trend detector operably coupled to the delay adjustment signal and configured to generate a locked signal indicative of a steady-state phase match between the external clock signal and the output clock signal.

In a further embodiment of the present invention, a memory device includes a memory array with an output driver coupled thereto and a delay locked loop circuit operably coupled between the output driver and configured to couple with an external clock signal. The delay locked loop circuit includes a phase detector configured to generate a delay adjustment signal in response to comparison of a forward path signal indicative of an external clock signal and a feedback signal indicative of an output clock signal. The delay locked loop circuit further includes a trend detector operably coupled to the delay adjustment signal and configured to generate a locked signal indicative of a steady-state phase match between the external clock signal and the output clock signal.

In yet another embodiment of the present invention, a semiconductor wafer is disclosed and comprises a plurality of integrated circuit memory devices wherein each memory device includes a memory array with an output driver coupled thereto and a delay locked loop circuit operably coupled between the output driver and further configured to couple with an external clock signal. The delay locked loop circuit includes a phase detector configured to generate a delay adjustment signal in response to comparison of a forward path signal indicative of an external clock signal and a feedback signal indicative of an output clock signal. The delay locked loop circuit further includes a trend detector operably coupled to the delay adjustment signal and configured to generate a locked signal indicative of a steady-state phase match between the external clock signal and the output clock signal.

In yet a further embodiment of the present invention, an electronic system includes a processor, at least one of an input device and an output device operably coupled to the processor, and a memory device operably coupled to the processor. The memory device includes a memory array with an output driver coupled thereto and a delay locked loop circuit operably coupled between the output driver and configured to couple with an external clock signal. The delay locked loop circuit includes a phase detector configured to generate a delay adjustment signal in response to a comparison of a forward path signal indicative of an external clock signal and a feedback signal indicative of an output clock signal. The delay locked loop circuit further includes a trend detector operably coupled to the delay adjustment signal and configured to generate a locked signal indicative of a steady state phase match between the external clock signal and the output clock signal.

In yet an additional embodiment of the present invention, a clock synchronization detection method includes generating a delay adjustment signal in response to a comparison of a forward path signal indicative of an external clock signal and a feedback signal indicative of an output clock signal. A trend in the delay adjustment signal is detected and a locked signal indicative of a steady-state phase match between the external clock signal and the output clock signal is generated.

### BRIEF DESCRIPTION OF THE SEVERAL VIEWS OF THE DRAWINGS

In the drawings, which illustrate what is currently considered to be the best mode for carrying out the invention:

FIG. 1 is a block diagram of a clock synchronization circuit for detecting a locked state between an input clock and an output clock, in accordance with an embodiment of the present invention;

FIG. 2 is a block diagram of a clock synchronization circuit for detecting a locked state between an input clock and an output clock, in accordance with another embodiment of the present invention;

FIG. 3 is a block diagram of a clock synchronization circuit for detecting a locked state between an input clock and an output clock, in accordance with a further embodiment of the present invention;

FIG. 4 is a block diagram of a clock synchronization circuit for detecting a locked state between an input clock and an output clock, in accordance with yet another embodiment of the present invention;

FIG. 5 is a timing diagram illustrating a generation of a locked signal indicative of a locked steady-state of a clock synchronization circuit, according to one or more embodiments of the present invention;

FIG. 6 is a block diagram of a memory device including a clock synchronization circuit capable of indicating a locked steady-state of the circuit, in accordance with an embodiment of the present invention;

FIG. 7 is a block diagram of an electronic system including a clock synchronization circuit, in accordance with an embodiment of the present invention; and

FIG. 8 illustrates a semiconductor wafer including one or more devices which further include a clock synchronization circuit capable of indicating a locked steady-state, in accordance with an embodiment of the present invention.

### DETAILED DESCRIPTION OF THE INVENTION

In the following description of the various embodiments, reference is made to the accompanying drawings, which form a part hereof and show, by way of illustration, specific embodiments in which the invention may be practiced. These embodiments are described in sufficient detail to enable those skilled in the art to practice the invention, and it is to be understood that other embodiments may be utilized, and that variations and changes may be made without departing from the scope of the present invention.

The various circuits, systems, and methods of the various embodiments of the present invention detect a quiescent or phase-equal state for a clock synchronization circuit, an example of which is a delay locked loop circuit. The various embodiments of the present invention monitor an output of the circuit's phase detector and react to trends in the phase detector output signal. Accordingly, such circuits, systems and methods generate an indication of the quiescent or steady-state regardless of the accuracy of the phase detector or the range of the input clock jitter.

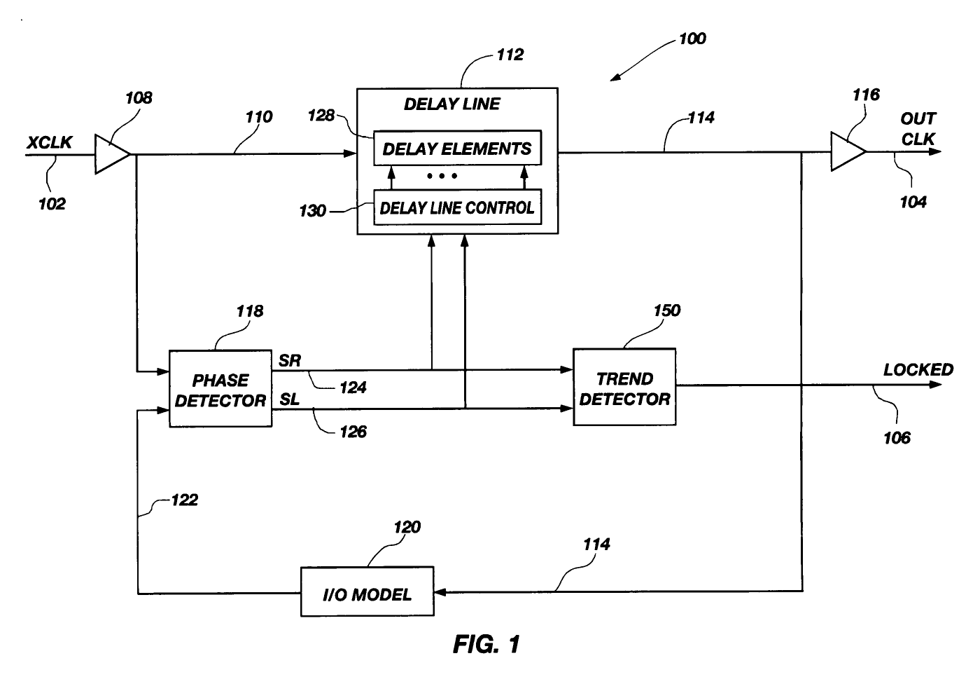

In synchronous circuits, such as dynamic random access memory (DRAM), the data out clock should be locked or maintain a fixed relationship to the external clock for high-speed performance. Clock-access and output-hold times are determined by the delay time of the internal circuits. FIG. 1 is a block diagram of a clock synchronization and locked detection circuit for synchronizing and detecting a locked state between an input clock and an output clock, in accordance with an embodiment of the present invention.

A clock synchronization circuit 100 may be configured as a DLL circuit. In one embodiment of the present invention, the clock synchronization circuit 100 includes an input driver 108, a delay line 112, an output driver 116, a phase detector 118, an I/O model 120 and a trend detector 150. A DLL portion of the circuit 100 includes the delay line 112, the I/O model 120, and the phase detector 118. When operative, an external clock signal 102 passes through the input driver 108, generating a forward path input signal 110, and further passes through to delay line 112. Delay line 112 may include a fine adjustment delay line and/or a coarse adjustment delay line (not shown). Delay line 112 delays the signal received from input driver 108, and outputs a delayed clock signal 114. The delay clock signal 114 is also fed back to and delayed by I/O model 120.

I/O model 120 provides delay elements that model the intrinsic delay of input driver 108 and output driver 116 to form a comparison or reference delay path. I/O model 120 generates a feedback path input signal 122 which is provided to phase detector 118. Phase detector 118 compares the phase of the forward path input signal 110 with the phase of the feedback path input signal 122. Phase detector 118 then outputs one or more delay adjustment signals (e.g., Shift Right SR 124 and Shift Left SL 126) to a delay line controller 130 (e.g., a shift register) which adjusts one or more delay elements 128 forming delay within the delay line 112. The delay formed in delay line 112 is used to synchronize the external clock signal 102 with the output clock signal 104.

The circuit 100, in addition to operating as a DLL circuit for the generation of an output clock signal 104 that is in phase with the external clock signal 102, generates a locked signal 106 identifying attainment of an in-phase or locked state of the DLL portion of the circuit 100. A trend detector 150 is coupled to the delay adjustment signals 124, 126 to monitor the trend of the adjustment signals as generated by the phase detector 118 in response to phase differences between the forward path input signal 110 and the feedback path input signal 122. Appreciable variations in the phase relationship of the forward path input signal 110 and the feedback path input signal 122 indicate that the DLL portion of circuit 100 is not in a locked state and that further adjustments to the delay line 112 are warranted in order to pull the phase of the output clock signal 104 into operational specifications of any device that relies upon the clock generation and synchronization capabilities of the DLL circuit. Accordingly, when the delay line 112 is adjusted to meet operational specifications, the trend detector 150 deasserts locked signal 106 indicating the DLL circuit is not yet operating within the desired specifications.

While appreciable variations in the delay adjustment signals 124, 126 as generated by the phase detector 118 are indicative of an unlocked DLL circuit, acceptable variations in the delay adjustment signals 124, 126 may result from various sources such as jitter on the external clock signal 102 as well as from resolution capabilities of the phase detector 118 that result in sampling oscillations at the output of the phase detector 118. Accordingly, when the delay adjustment signals 124,126 fluctuate within a defined or acceptable region, the DLL circuit is actually locked within operational specifications. Therefore, the trend detector 150 generates the locked signal 106 indicating that the DLL is operating within an acceptable phase differential between the forward path input signal 110 and the feedback path input signal 122.

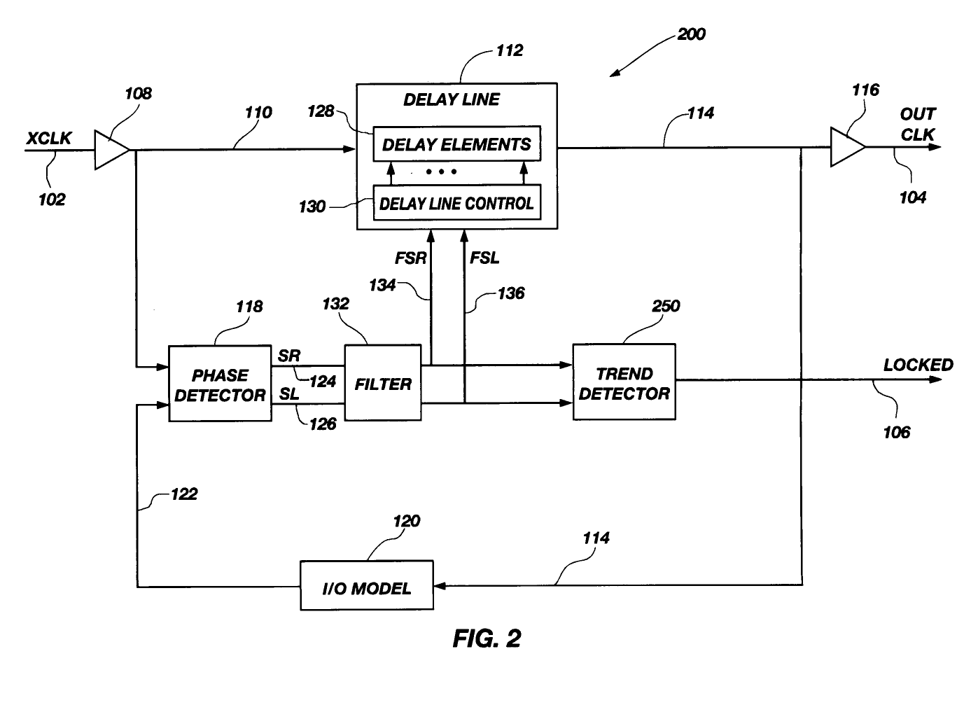

FIG. 2 is a block diagram of a clock synchronization and lock detection circuit for synchronizing and detecting a locked state between an input clock and an output clock, in accordance with another embodiment of the present invention. As stated, one or more factors such as jitter on the external clock signal 102 as well as oscillations from the sampling resolution of the phase detector 118 may cause acceptable variations in delay adjustment signals 124, 126 which is further indicative of an acceptable phase differential between the forward path input signal 110 and the feedback path input signal 122. In FIG. 2, a clock synchronization circuit 200 includes a filter 132 which absorbs or buffers higher frequency oscillations generated by the phase detector 118. Accordingly, the delay line 112 as well as the trend detector 250 are protected from being subjected to similar oscillations that are within an in-phase or steady-state tolerance.

The circuit 200 includes input driver 108, delay line 112, output driver 116, I/O model 120, and phase detector 118 as described with respect to FIG. 1. Circuit 200 further includes filter 132 for receiving delay adjustment signals 124, 126 and generating delay adjustment signals 134, 136. Filter 132 may be implemented as an averaging filter or according to one or more other digital filtering techniques, an example of which includes counters that buffer a configurable quantity of successive shifts before initiating a delay adjustment signal to the delay line 112 directing modification of the delay and affecting the locked state of the trend detector 250.

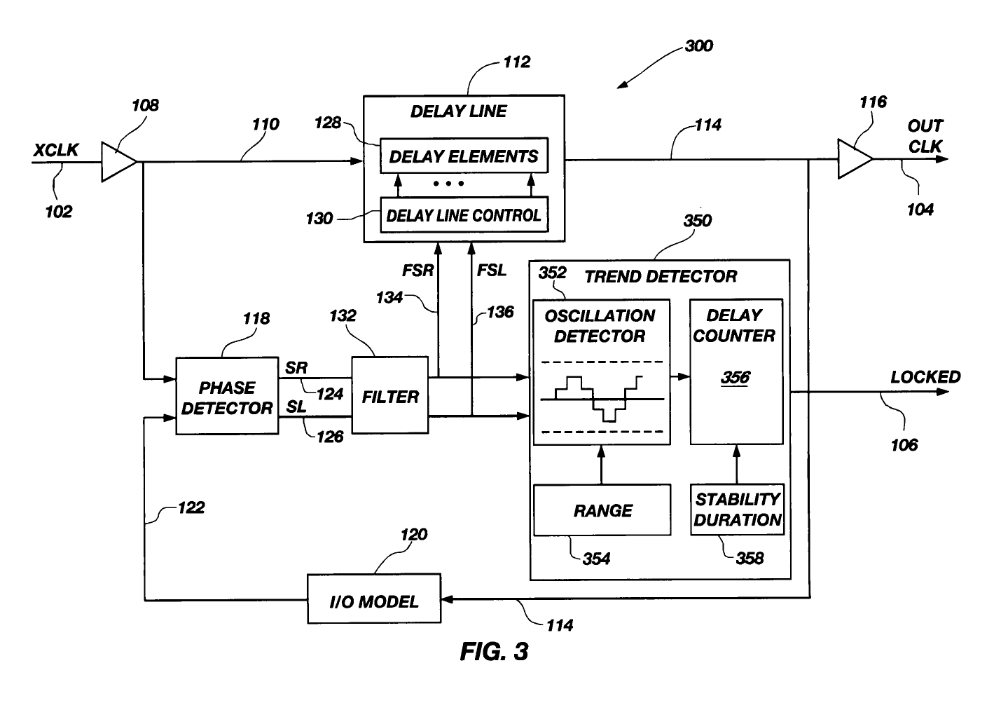

FIG. 3 is a block diagram of a clock synchronization and lock detection circuit for synchronizing and detecting a locked state between an input clock and an output clock, in accordance with a further embodiment of the present invention. As stated, external circuits from the DLL portion as well as other synchronization circuits rely upon knowledge of an in-phase or locked state of the DLL portion of the clock synchronization circuit. As stated, the ability to detect a locked state based solely upon a deadband or hysteresis of a phase detector is problematic when clock jitter specifications relating to the external clock signal increase as well as when resolution specification of the phase detector also increase. Accordingly, a trend detector generates a locked signal based upon the trend of the delay adjustment signals.

In FIG. 3, a clock synchronization circuit 300 includes an input driver 108, a delay line 112, an output driver 116, an I/O model 120, a phase detector 118 and an optional filter 132 for absorbing higher frequency oscillations as described with respect to FIG. 2. Circuit 300 further includes a trend detector 350 for detecting a locked or in-phase state of the clock synchronization circuit. Trend detector 350 receives delay adjustment signals, such as delay adjustment signals 134, 136, and generates an in-phase or locked signal 106. In the present embodiment, trend detector 350 is configured to detect oscillations in the delay adjustment signals generated by the phase detector 118 which may be further modified by the optional filter 132. Accordingly, trend detector 350 includes an oscillation detector 352 configured to track shifts within delay adjustment signals that specify an increase or decrease in the differential phases as determined by the phase detector 118. Oscillation detector 352 compares the oscillation of the delay adjustment signals against a definable or determined range 354 which defines an oscillation envelope of an acceptable range corresponding to an in-phase or locked state of the DLL portion of the circuit 300. Specification of the determined range 354 may be a function of the jitter specifications for the external clock signal 102 as well as the resolution of the phase detector 118. Furthermore, the determined range 354 may be one-time configurable to a specific device that incorporates circuit 300 or reconfigurable for varying operational specifications for a device that incorporates circuit 300.

In yet a further embodiment of the present invention, trend detector 350 may further include additional stabilization features that require oscillation stability prior to generating a locked signal 106 specifying an acceptably stable or steady-state of the DLL portion of circuit 300. Accordingly, trend detector 350 may further include a delay counter 356 coupled to the oscillation detector 352. Delay counter 356 is configured to generate the locked signal 106 following a stability duration 358 of the output of the oscillation detector. The stability duration 358 further acts to suppress transient occurrences of an in-phase or locked state that may result in a false detection of a quiescent or steady-state condition of circuit 300. Specification of the stability duration 358 may be a function of startup timing requirements as well as transient conditions during the startup phase of the circuit 300. Furthermore, the stability duration 358 may be one-time configurable to a specific device that incorporates circuit 300 or reconfigurable for varying operational specifications for a device that incorporates circuit 300.

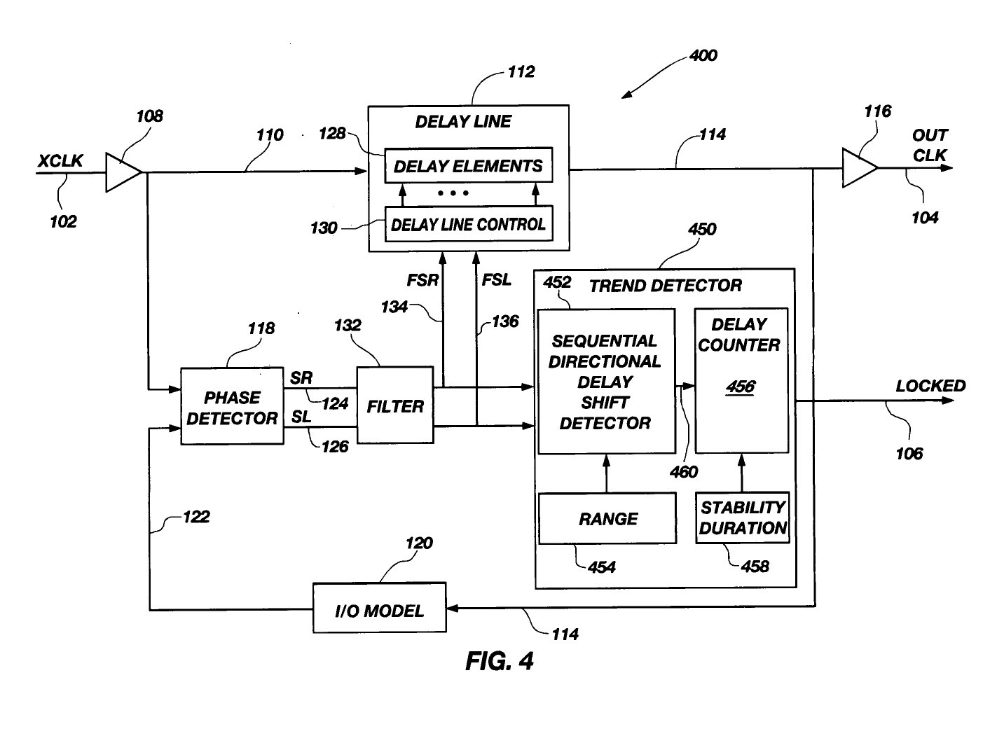

FIG. 4 is a block diagram of a clock synchronization and lock detection circuit for synchronizing and detecting a locked state between an input clock and an output clock, in accordance with a yet another embodiment of the present invention. As stated, external circuits from the DLL portion as well as other synchronization circuits rely upon knowledge of a phase locked state of the DLL portion of the synchronization circuit. As stated, the ability to detect a locked state based solely upon a deadband or hysteresis of a phase detector is problematic when clock jitter specifications relating to the external clock signal increase as well as when resolution specification of the phase detector also increase. Accordingly, a trend detector generates a locked signal based upon the trend of delay adjustment signals.

In FIG. 4, a clock synchronization circuit 400 includes an input driver 108, a delay line 112, an output driver 116, an I/O model 120, a phase detector 118 and an optional filter 132 for absorbing higher frequency oscillations as described with respect to FIG. 2. Circuit 400 further includes a trend detector 450 for detecting a locked or in-phase state of the clock synchronization circuit. Trend detector 450 receives delay adjustment signals, such as delay adjustment signals 134, 136, and generates an in-phase or locked signal 106. In the present embodiment, trend detector 450 is configured to detect sequential directional delay shifts in the delay adjustment signals generated by the phase detector 118 which may be further modified by the optional filter 132. Accordingly, trend detector 450 includes sequential directional delay shift detector 452 configured to track shifts within delay adjustment signals that specify an increase or decrease in the differential phases as determined by the phase detector 118.

Sequential directional delay shift detector 452 receives the delay adjustment signals either directly from the phase detector 118 or as modified by an optional filter 132. Sequential directional delay shift detector 452 monitors the delay adjustment signals for sustained drift in either an increased or decreased delay direction for a definable or determined range 454 which defines a sequential envelope of an acceptable range corresponding to an in-phase or locked state of the DLL portion of circuit 400.

In one embodiment of the present invention, sequential directional delay shift detector 452 is configured as a counter that monitors the number of consecutive shifts in a given delay modification direction (e.g., left shift increases delay, right shift decreases delay). If a number, N, of consecutive same-direction sequential delay shifts of a delay adjustment signal is detected (i.e., a range of N sequential shifts of the delay adjustment signal in the same direction where N is a positive integer), the DLL portion of the circuit 400 is not in an in-phase or locked state. Specification of the determined range 454 may be a function of the jitter specifications for the external clock signal 102 as well as the resolution of the phase detector 118. Furthermore, the determined range 454 may be one-time configurable to a specific device that incorporates circuit 400 or reconfigurable for varying operational specifications for a device that incorporates circuit 400.

In yet a further embodiment of the present invention, trend detector 450 may further include additional stabilization features that require sequential directional delay shifting stability prior to generating a locked signal 106 specifying an acceptably stable or steady-state of the DLL portion of circuit 400. Accordingly, trend detector 450 may further include a delay counter 456 coupled to the sequential directional delay shift detector 452. Delay counter 456 is configured to generate the locked signal 106 following a stability duration 458 of the output of the sequential directional delay shift detector. The stability duration 458 further acts to suppress transient occurrences of an in-phase or locked state that may result in a false detection of a quiescent or steady-state condition of circuit 400. Specification of the stability duration 458 may be a function of startup timing requirements as well as transient conditions during the startup phase of the circuit 400. Furthermore, the stability duration 458 may be one-time configurable to a specific device that incorporates circuit 400 or reconfigurable for varying operational specifications for a device that incorporates circuit 400.

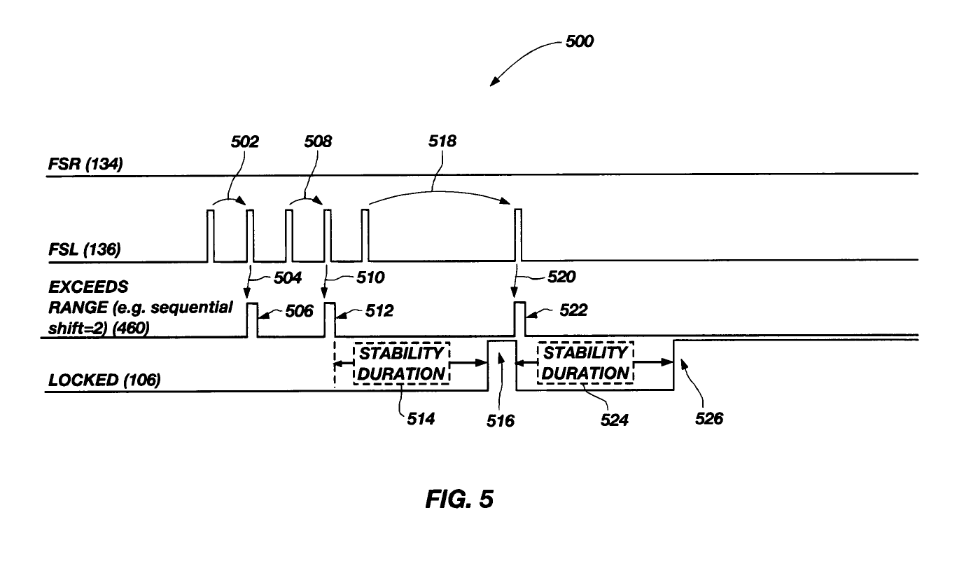

FIG. 5 is a timing diagram of an embodiment incorporating a sequential directional delay shift detector, in accordance with an embodiment of the present invention. By way of example and not limitation, and for illustrative purposes, the timing diagram 500 of FIG. 5 illustrates a determined range 454 (FIG. 4) set to 2 (two) for designating an excessive quantity of sequential directional delay shifts indicative of a DLL portion of circuit 400 (FIG. 4) that is not in-phase or locked. Sequential directional delay shift detector 452 (FIG. 4) receives delay adjustment signals 134, 136 in one or more state-storing elements (not shown) such as one or more counters (also not shown). Sequential direction delay shift detector 452 monitors the number of consecutive shift signals in a delay increase or decrease direction (e.g., FSR 134 and FSL 136). If the number, N, of consecutive shifts 502 in the same direction exceeds 504 the determined range 454, then the DLL portion of circuit 400 is not in-phase or locked. Such an occurrence creates a pulse 506 which resets delay counter 456 (FIG. 4). If a subsequent quantity, N, of consecutive shifts 508 in the same direction exceeds 510 the determined range 454, then the DLL portion of circuit 400 remains in a not in-phase or locked state. Such an occurrence creates a pulse 512 which again resets delay counter 456 (FIG. 4). When a stability duration 458 (FIG. 4) is achieved 514, then a locked signal pulse 516 is asserted on locked signal 106 (FIG. 4). When or if, however, a subsequent quantity, N, of consecutive shifts 518 in the same direction exceeds 520 the determined range 454, then the DLL portion of circuit 400 returns to a not in-phase or locked state. Such an occurrence creates a pulse 522 which again resets delay counter 456 (FIG. 4). When a stability duration 458 (FIG. 4) is achieved 524, then a locked signal pulse 526 is asserted on locked signal 106 (FIG. 4).

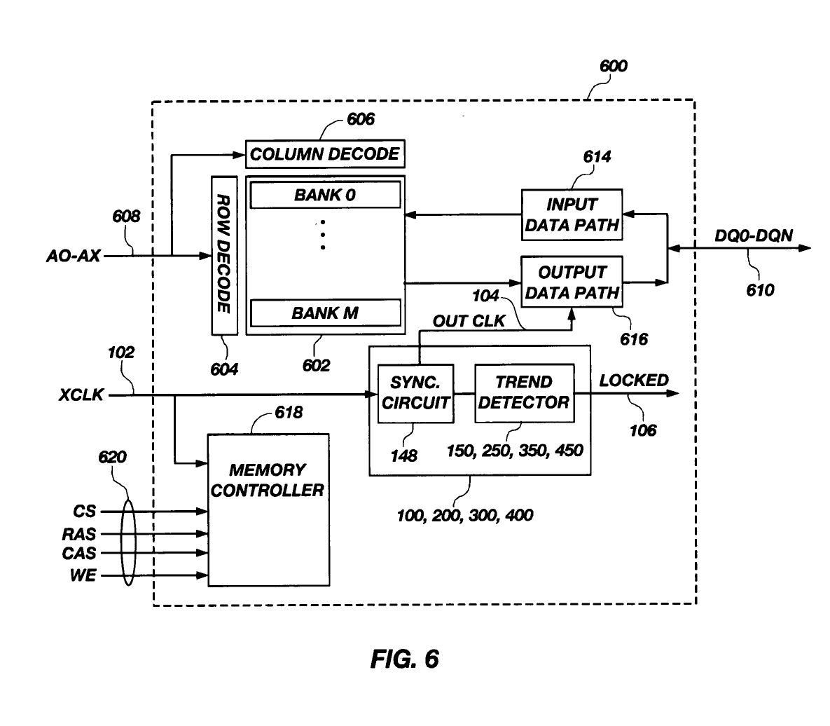

FIG. 6 is a block diagram of a memory device including a clock synchronization circuit capable of indicating a locked or steady-state of the circuit, in accordance with an embodiment of the present invention. A memory device 600 includes a main memory 602 having a plurality of memory cells arranged in rows and columns. The memory cells are grouped into a plurality of memory banks indicated by bank 0 through bank M. Row decode 604 and column decode 606 access the memory cells in response to address signals A0 through AX (A0-AX) on address lines (or address bus) 608. A data input path 614 and a data output path 616 transfer data between banks 0-M and data lines (or data bus) 610. Data lines 610 carry data signals DQ0 through DQN. A memory controller 618 controls the modes of operations of memory device 600 based on control signals on control lines 620. The control signals include, but are not limited to, a Chip Select signal CS, a Row Access Strobe signal RAS, a Column Access Strobe CAS signal, a Write Enable signal WE, and an external signal XCLK 102.

Memory device 600 further includes a clock synchronization circuit from one of the various embodiments (100 (FIG. 1), 200 (FIG. 2), 300 (FIG. 3), 400 (FIG. 4)) for receiving the XCLK signal 102 and generating an output clock signal 104. The output clock signal 104 serves as a clock signal to control a transfer of data on data output path 616. The clock synchronization circuit 100, 200, 300, 400 includes a DLL portion 148 for generating a synchronous output clock signal 104 from a received external clock signal 102. The synchronization circuit 100, 200, 300, 400 further includes a trend detector from one of the various embodiments (150 (FIG. 1), 250 (FIG. 2), 350 (FIG. 3), 450 (FIG. 4)) for generating a locked signal 106 indicative of a locked or steady-state of the clock synchronization circuit.

In some embodiments, memory device 100, 200, 300, 400 may be a dynamic random access memory (DRAM) device. In other embodiments, memory device 100, 200, 300, 400 may be a static random access memory (SRAM), or flash memory. Examples of DRAM devices include synchronous DRAM commonly referred to as SDRAM (synchronous dynamic random access memory), SDRAM II, SGRAM (synchronous graphics random access memory), DDR SDRAM (double data rate SDRAM), DDR II SDRAM, and Synchlink or Rambus DRAMs. Those skilled in the art recognize that memory device 100, 200, 300, 400 includes other elements, which are not shown for clarity.

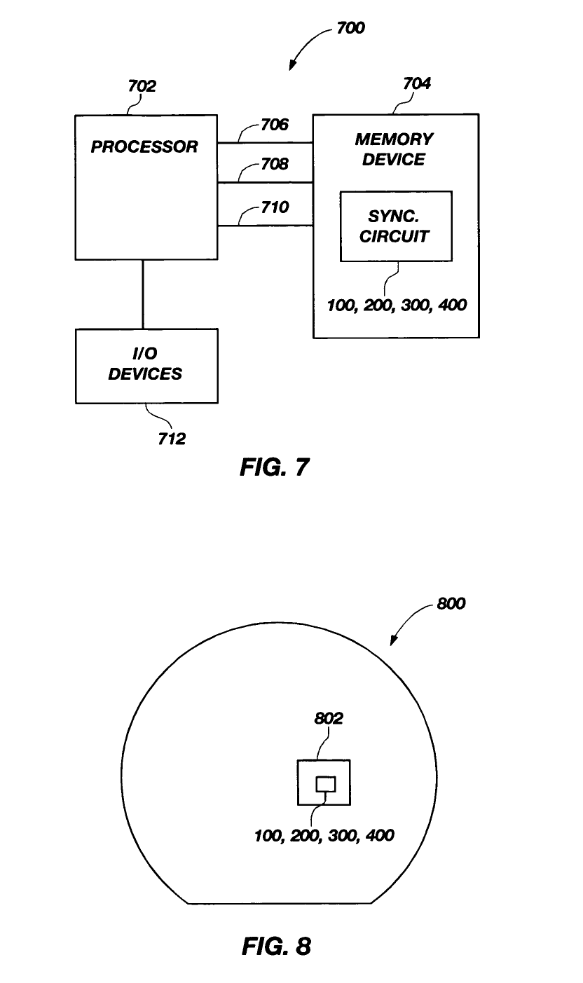

FIG. 7 is a block diagram of an electronic system, in accordance with an embodiment of the present invention. Electronic system 700 includes a processor 702, a memory device 704, and one or more I/O devices 712. Memory device 704 represents memory device 600 of one or more embodiments of the present invention. Processor 702 may be a microprocessor, digital signal processor, embedded processor, microcontroller, or the like. Processor 702 and memory device 704 communicate using address signals on lines 708, control signals on lines 710, and data signals on lines 706.

Memory device 704 includes a synchronization circuit 100 (FIG. 1), 200 (FIG. 2), 300 (FIG. 3), 400 (FIG. 4). According to one or more embodiments of the present invention and during a memory operation, processor 702 provides certain combination of input signals and address signals to memory device 704 via lines 708 and lines 710. The input signals are similar to the RAS, CAS, WE, CS signals known by those of ordinary skill in the art.

FIG. 8 illustrates a semiconductor wafer, including one or more devices, which further includes a clock synchronization circuit capable of indicating a locked or steady-state, in accordance with an embodiment of the present invention. A wafer 800, which includes multiple integrated circuits 802, at least one of which incorporates a clock synchronization circuit 100 (FIG. 1), 200 (FIG. 2), 300 (FIG. 3), 400 (FIG. 4), in accordance with one or more embodiments of the present invention. In one embodiment, the wafer includes a semiconductor substrate, such as a silicon, germanium, gallium arsenide or indium phosphide wafer. In other embodiments, the substrate can be an insulator such as glass or aluminum, or a metal such as stainless steel or iron. After processing the substrate to form the various circuit elements of the clock synchronization circuit, and any other circuit elements included in the integrated circuit, each integrated circuit 802 may be singulated into individual semiconductor dice, packaged, and incorporated into an electronic system. When the wafer includes integrated memory circuits, the substrate also includes a plurality of memory cells supported by the substrate.

Although the foregoing description contains many specifics, these should not be construed as limiting the scope of the present invention, but merely as providing illustrations of some exemplary embodiments. Similarly, other embodiments of the invention may be devised which do not depart from the spirit or scope of the present invention. Features from different embodiments may be employed in combination. The scope of the invention is, therefore, indicated and limited only by the appended claims and their legal equivalents, rather than by the foregoing description. All additions, deletions, and modifications to the invention, as disclosed herein, which fall within the meaning and scope of the claims are to be embraced thereby.

What is claimed is:

1. A clock synchronization circuit, comprising:
a delay line having first and second inputs and an output, the first input configured to receive an external clock signal via an input driver and the output configured to couple with an output driver to generate an output clock signal;
an I/O model having an output and an input, the input of the I/O model configured to couple with the output of the delay line, the I/O model further configured to model delay of the output driver and the input driver;
a phase detector including forward and feedback path inputs and an output operably coupled to the second input of the delay line, the forward path input coupled to the first input of the delay line and the feedback path input coupled to the output of the I/O model, the phase detector configured to generate a delay adjustment signal; and
a trend detector having an input operably coupled to the second input of the delay line and configured to generate a locked signal on an output, the locked signal indicative of an in-phase steady-state between the external clock signal and the output clock signal.

2. The circuit of claim 1, further comprising a filter operably coupled between the phase detector and the delay line and the trend detector, the filter configured to suppress noise variations from the output of the phase detector prior to being received at the delay line and the trend detector.

3. The circuit of claim 1, wherein the trend detector comprises an oscillation detector having an input operably coupled to the second input of the delay line and configured to generate the locked signal, the locked signal indicative of the in-phase steady-state between the external clock signal and the output clock signal.

4. The circuit of claim 3, wherein the oscillation detector is configured to be configurable to a range of the in-phase steady-state of the external clock signal and the output clock signal.

5. The circuit of claim 4, wherein the trend detector further comprises a delay counter operably coupled to the oscillation detector, the delay counter configured to generate the locked signal following a stability duration when the delay adjustment signal remains within the range.

6. The circuit of claim 1, wherein the trend detector comprises a sequential directional delay shift detector having an input operably coupled to the second input of the delay line and configured to generate the locked signal, the locked signal indicative of the in-phase steady-state between the external clock signal and the output clock signal.

7. The circuit of claim 6, wherein the sequential directional delay shift detector is configured to be configurable to a range specifying the in-phase steady-state between the external clock signal and the output clock signal.

8. The circuit of claim 7, wherein the trend detector further comprises a delay counter operably coupled to the sequential directional delay shift detector, the delay counter configured to generate the locked signal following a stability duration when the delay adjustment signal remains within the range.

9. A delay locked loop circuit, comprising:
a phase detector configured to generate a delay adjustment signal in response to comparison of a forward path signal indicative of an external clock signal and a feedback path signal indicative of an output clock signal; and
a trend detector operably coupled to the delay adjustment signal and configured to generate a locked signal indicative of an in-phase steady-state between the external clock signal and the output clock signal.

10. The delay locked loop circuit of claim 9, wherein the trend detector is configured to monitor oscillations of the delay adjustment signal and generate the locked signal when the oscillations remain within a range.

11. The delay locked loop circuit of claim 10, wherein the trend detector is further configured to delay generation of the locked signal until the oscillations remain within the range for a stability duration.

12. The delay locked loop circuit of claim 9, wherein the trend detector is configured to detect sequential directional delay shifts of the delay adjustment signal and generate the locked signal when the shifts remain within a range.

13. The delay locked loop circuit of claim 12, wherein the trend detector is further configured to delay generation of the locked signal until the shifts remain within the range for a stability duration.

14. A memory device, comprising:
a memory array with an output driver coupled thereto; and
a delay locked loop circuit operably coupled between the output driver and configured to couple with an external clock signal, the delay locked loop circuit including:
a phase detector configured to generate a delay adjustment signal in response to comparison of a forward path signal indicative of an external clock signal and a feedback path signal indicative of an output clock signal; and
a trend detector operably coupled to the delay adjustment signal and configured to generate a locked signal indicative of an in-phase steady-state between the external clock signal and the output clock signal.

15. The memory device of claim 14, wherein the trend detector is configured to monitor oscillations of the delay adjustment signal and generate the locked signal when the oscillations remain within a range.

16. The memory device of claim 15, wherein the trend detector is further configured to delay generation of the locked signal until the oscillations remain within the range for a stability duration.

17. The memory device of claim 14, wherein the trend detector is configured to detect sequential directional delay shifts of the delay adjustment signal and generate the locked signal when the shifts remain within a range.

18. The memory device of claim 17, wherein the trend detector is further configured to delay generation of the locked signal until the shifts remain within the range for a stability duration.

19. A semiconductor wafer comprising a plurality of integrated circuit memory devices, each memory device comprising:
a memory array with an output driver coupled thereto; and
a delay locked loop circuit operably coupled between the output driver and configured to couple with an external clock signal, the delay locked loop circuit including:
a phase detector configured to generate a delay adjustment signal in response to comparison of a forward path signal indicative of an external clock signal and a feedback path signal indicative of an output clock signal; and
a trend detector operably coupled to the delay adjustment signal and configured to generate a locked signal indicative of an in-phase steady-state between the external clock signal and the output clock signal.

20. An electronic device, comprising:
a processor;
at least one of an input device and an output device operably coupled to the processor; and
a memory device operably coupled to the processor, the memory device including a memory array with an output driver coupled thereto and a delay locked loop circuit operably coupled between the output driver and configured to couple with an external clock signal, the delay locked loop circuit including:
a phase detector configured to generate a delay adjustment signal in response to comparison of a forward path signal indicative of an external clock signal and a feedback path signal indicative of an output clock signal; and
a trend detector operably coupled to the delay adjustment signal and configured to generate a locked signal indicative of an in-phase steady-state between the external clock signal and the output clock signal.

21. The electronic system of claim 20, wherein the trend detector is configured to monitor oscillations of the delay adjustment signal and generate the locked signal when the oscillations remain within a range.

22. The electronic system of claim 21, wherein the trend detector is further configured to delay generation of the locked signal until the oscillations remain within the range for a stability duration.

23. The electronic system of claim 20, wherein the trend detector is configured to detect sequential directional delay shifts of the delay adjustment signal and generate the locked signal when the shifts remain within a range.

24. The electronic system of claim 23, wherein the trend detector is further configured to delay generation of the locked signal until the shifts remain within the range for a stability duration.

25. A signal locking indication method, comprising:
generating a delay adjustment signal in response to comparison of a forward path signal indicative of an external clock signal and a feedback path signal indicative of an output clock signal; and
detecting a trend of the delay adjustment signal; and
generating a locked signal indicative of an in-phase steady-state between the external clock signal and the output clock signal.

26. The method of claim 25, wherein the detecting a trend comprises detecting oscillations of the delay adjustment signal and generating the locked signal when the oscillations remain within a range.

27. The method of claim 26, further comprising delaying generation of the locked signal until the oscillations remain within the range for a stability duration.

28. The method of claim 25, wherein the detecting a trend comprises detecting sequential directional delay shifts of the delay adjustment signal and generating the locked signal when the shifts remain within a range.

29. The method of claim 28, further comprising delaying generation of the locked signal until the shifts remain within the range for a stability duration.
